(19) United States
(12) Patent Application Publication
(10) Pub. No.: US 2002/0011891 A1
(43) Pub. Date: Jan. 31, 2002

(54) Switching control circuit

(76) Inventors: Han Martijn Schuurmans, Nijmegen (NL); Quino Alexander Sandifort, Nijmegen (NL)

Correspondence Address: U.S. Philips Corporation, 580 White Plains Road, Tarrytown, NY, 10591, US

(21) Appl. No.: 09/906,350

(22) Filed: Jul. 16, 2001

(30) Foreign Application Priority Data
Jul. 17, 2000 (EP) 00202517.9

(51) Int. Cl. H03K 17/00

(52) U.S. Cl. 327/365

(57) ABSTRACT

To switch a switch of an audio source for example the problem exists that switching noise can occur.

The invention proposes a switching control circuit overcoming the problems of the prior art devices.

The switching control circuit according to the invention comprises means to generate a switch control signal which comprises several transitions from high to low and vice versa during one operation from a first to a second state or vice versa.

The invention relates to a switching control circuit.

The invention further relates to an audio device.

Switching control circuits are used for controlling a switch of, for example, an audio source etc.

When listening to for example an audio source that is switched over to another input channel, or when another channel is added or when the volume is changed where the step-size is too large, this will be audible as hearing clicks. There are basically three types of clicks: power on/off; channel switching/adding; and volume change with too large steps.

The click that is produced is caused by a change in output level in a very short time.

In the case of channel switching or power on click the output level will undergo a DC change in a certain time (dV/dt). This DC change will be audible if the change is in the order of a 1 milliVolt (60 dB-70 dB below full scale) and the time is less than 100 millisec. In general if the dV/dt is too large (>0.01 Volt/s) this will become audible and unwanted.

An object of the invention is to provide a switching control circuit not having the disadvantageous of the prior art. To this end a switching control circuit according to the invention comprises the features of claim 1.

The invention lies not in lowering the DC step, which is very common in analog circuitry but in making the switch time larger.

During one operation from a first state to a second state the analog switch is switched on and off with a frequency which is lying outside the frequency band of interest.

This switch control signal will then be changed in duty-cycle from 0% (switch is fully off) to 100% (switch is fully on).

If the duty-cycle is changed from 0% to 100% in a time which is larger than 100 millisec. the actual plop/click will not be heard.

Embodiments of the invention are described in the dependent claims.

These and other aspects of the invention will be apparent from and elucidated with references to the examples described hereinafter, herein shows:

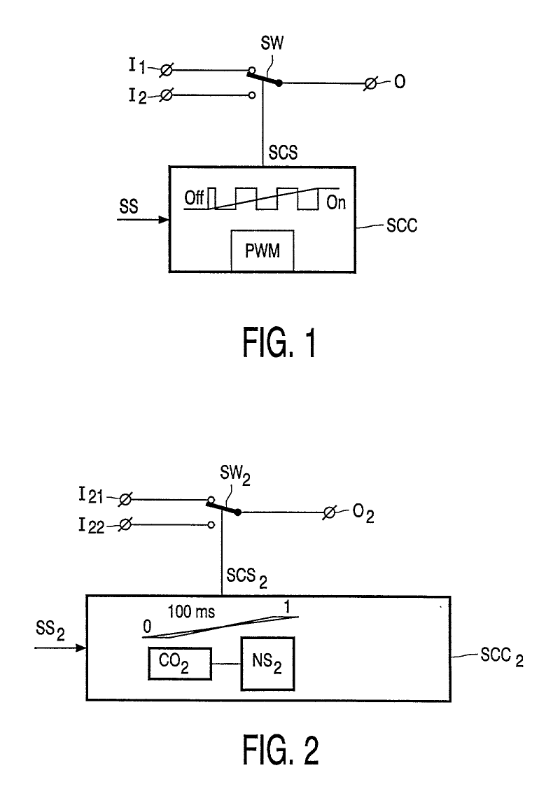

FIG. 1, a first example of a switch control circuit according to the invention, and

FIG. 2, a second example of a switch control circuit according to the invention.

FIG. 1 shows a switching control circuit SCC. The switching control circuit receives a switching signal ss and supplies a switching control signal scs.

The switching control circuit comprises a pulse-width modulator PWM to supply as a switching control signal scs a pulse-width modulated signal. For example, the control frequency can be 44.1 kHz. The duty-cycle of the pulse-width modulated signal will change from 0% to 100% in, for example, 100 ms.

It is important that the pulse-width increment value is small (sufficient resolution) in this case 4410 increments will be given which results in a resolution of 5.1 nanosec. This is sufficient low, but it takes a system frequency of 200 MHz, which is rather high. The switching control signal scs causes the switch SW from one state to the other causing the signal path switched from input I1-output O to input I2-output O or vice versa.

FIG. 2 shows a second example of a switching control circuit SCC2. Also in this case the switching control circuit receives a switching signal ss2 and supplies a switching control signal scs2 to a switch SW2.

In this example the switching control circuit comprises a counter CO which counts from zero to one (floating point notation in 100 ms in this example). A noise-shaper NS2 receives as input signal the output signal of the counter CO2.

The noise-shaper converts this signal in a one-bit bit-stream. This bit-stream output is in this example the switching control signal scs2.

The ratio between the ones and zeros of the noise-shaper output represents the counter value. The ratio between the on and off time of the switch determines the amount of signal that passes from the input I21 or input I22 to the output O2. If the counter CO2 increments slowly from zero to one, the output signal fades from input I21 to input I22. The switching will in that case not be heard.

The above-described examples of a switching control circuit according to the invention can be used in combination with, for example, power on control. Nowadays by prior art devices, power on is done by slowly charging a capacitor. The voltage of the capacitor determines a maximum output level of, for example, a DA-converter or a power-amplifier.

By connecting the switch control circuit according to the invention the capacitor can be omitted. The time where the DA-converter or power-amplifier is fully switched on is determined by the time that the counter reaches its value one (FIG. 2).

As already mentioned the invention can be used for switching between input signals. DC offsets are of no interest when the switching control circuit is used. DC blocking capacitors can be omitted if they were used to filter out plops/clicks by prior art devices.

Also when volume control is done in steps which are too large, for example, 1 dB, than also the switching control circuit according to the invention can be used to smoothly switch over from one gain level to the adjacent gain level. This means the actual gain step can be larger, resulting in smaller analog area needed.

Further as a noise-shaper a first order noise-shaper is sufficient, but higher noise-shapers can be used.

Above the switching control circuit according to the invention is described on the basis of two examples. The man skilled in the art is well aware of a lot of amendments falling within the scope of the invention. The switching control circuit can be used in an audio device or other device needing a smoothly switching over/on.

1. Switching control circuit comprising an input for receiving an input signal indicating a required switching over of a switch, an output for supplying a switch control signal with a high and a low level to switch over the switch from a first to a second state or visa versa and means to generate this switch control signal which comprises several transitions from high to low and visa versa during one operation from a first to a second state or vice versa.

2. Switching control circuit according to claim 1, characterized in that a switching control circuit comprises a pulse-width modulator for supplying the switching control signal.

3. Switching control circuit according to claim 1, characterized in that a switching control circuit comprises a noise-shaper for supplying the switching control signal.

4. Switching control circuit according to claim 3, characterized in that the switching control circuit comprises a counter coupled to the input of noise-shaper.

5. Audio device comprising a switching control circuit as claimed in claim 1.
